(19) United States
(12) Patent Application Publication
(10) Pub. No.: US 2014/0328967 A1
(43) Pub. Date: Nov. 6, 2014

(54) MOLD AND METHOD FOR MANUFACTURING SAME

(71) Applicant: HON HAI PRECISION INDUSTRY CO., LTD., New Taipei (TW)

(72) Inventor: CHIA-LING HSU, Tu-Cheng (TW)

(73) Assignee: HON HAI PRECISION INDUSTRY CO., LTD., New Taipei (TW)

(21) Appl. No.: 14/265,380

(22) Filed: Apr. 30, 2014

(30) Foreign Application Priority Data
May 2, 2013 (TW) 102115676

(51) Int. Cl. B29C 45/37; C23C 16/455; C23C 16/40

(52) U.S. Cl. CPC B29C 45/37; C23C 16/403; C23C 16/45525
USPC 425/542; 427/135

(57) ABSTRACT

A method for creating a mold for an optical connector includes a main body and a film, the film is a compound of aluminum oxide and hexamethyldisilazane providing a non-stick and hard surface. The main body defines a cavity therein and the surfaces of the cavity are coated with the film.

### BACKGROUND

1. Field

The present disclosure relates to molds, and particularly to a mold for molding an optical fiber connector and a method for manufacturing the mold.

2. Background

Optical fiber connectors are usually molded by an injection molding process. A molding material of the optical fiber connector is typically polyetherimide (PEI) with a high viscosity coefficient. In the injection molding process, melted PEI is injected into a mold to form the optical fiber connector.

### BRIEF DESCRIPTION OF THE DRAWING

The components of the drawing are not necessarily drawn to scale, the emphasis instead being placed upon clearly illustrating the principles of the embodiments of the present disclosure.

FIG. 1 is a schematic view of a mold, according to an exemplary embodiment of the present disclosure.

FIG. 2 is an enlarged view of part II of the mold of FIG. 1.

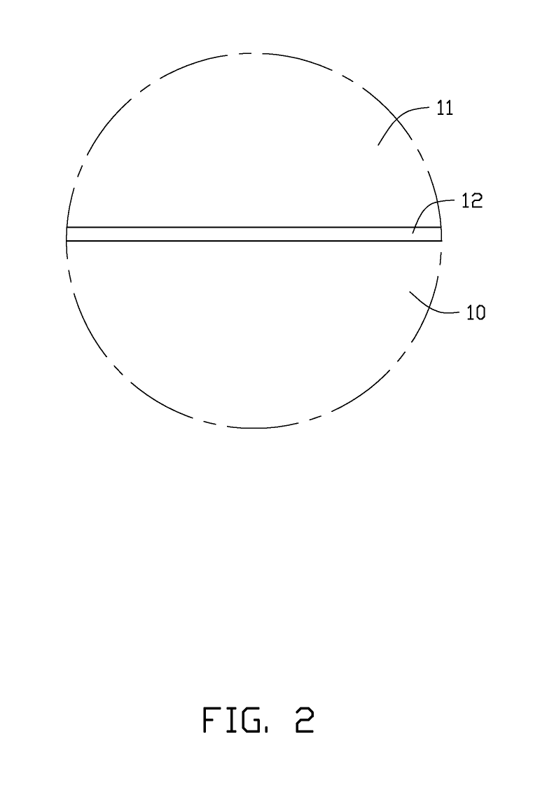

FIG. 3 is a schematic view of method for manufacturing a mold, according to an exemplary embodiment of the present disclosure.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.” The references “a plurality of” and “a number of” mean “at least two.”

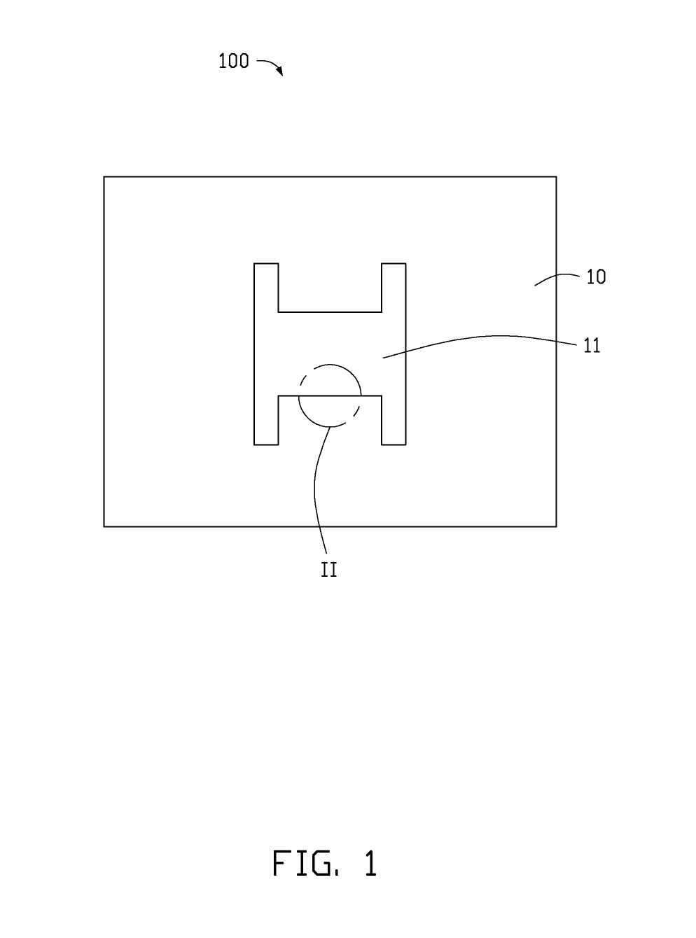

FIG. 1 illustrates one embodiment of a mold 100. The mold 100 includes a main body 10. The main body 10 defines a cavity 11. The mold 100 includes a film 12 compounded with aluminum oxide and hexamethyldisilazane (HDMS). The film 12 is formed on a side surface of the cavity 11.

A HDMS material has a low surface energy, and an aluminum oxide material has a high hardness. Therefore, the film 12 has non-stick properties and scratch resistance. In this embodiment, a thickness of the film 12 is about 100 nanometers.

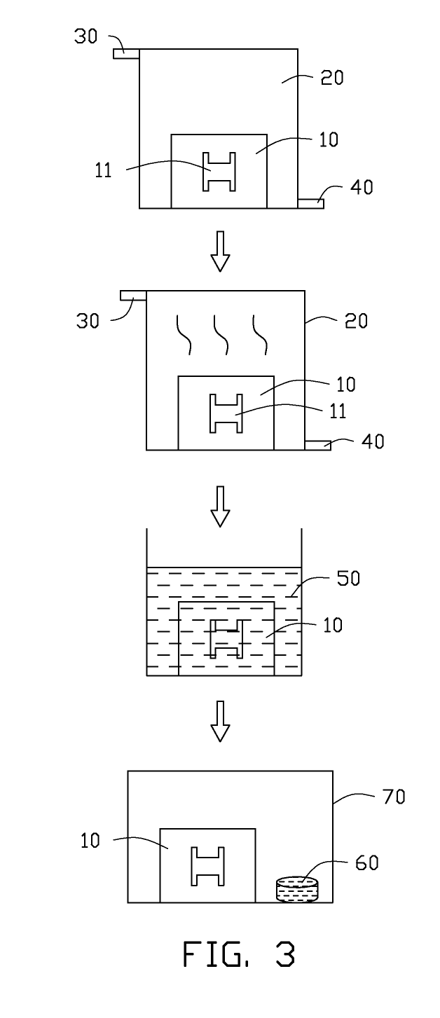

The mold 100 can be manufactured by a method illustrated in FIG. 3. The method includes the following steps:

A first chamber 20 is provided. The first chamber 20 includes a first valve 30 and a second valve 40. Air in the first chamber 20 can be exhausted through the first valve 30 and the second valve 40, and a predetermined gas(s) can be injected into the first chamber 20 through the first valve 30 and the second valve 40.

The main body 10 is positioned in the first chamber 20. Air is evacuated from the first chamber 10, and a pressure in the first chamber 20 is kept at about 10−3-10−5 torrs.

The main body 10 is heated to about 250° C., trimethyl aluminum (TMA) material and oxygen gas are alternately injected into the first chamber 20. In detail, the TMA is firstly injected into the first chamber 20 for a predetermined time, and when the TMA is dispersed in the first chamber 20, the oxygen is then injected into the first chamber 20 for another predetermined time. In this embodiment, the TMA is injected into the first chamber 20 for about 1-2 milliseconds, and the oxygen is injected into the first chamber 20 for about 1-2 milliseconds. The TMA and the oxygen react with each other in the first chamber 20 to form aluminum oxide and the aluminum oxide deposits on a side surface of the cavity 11 to form an aluminum oxide film. The aluminum oxide film is formed by an atomic layer deposition (ALD) process. A reaction time in the first chamber 20 can be controlled to generate a required thickness of the aluminum oxide film. In this embodiment, the thickness of the aluminum oxide film is about 100 nanometers.

Because the TMA is injected into the first chamber 20 before the oxygen, an oxicracking of the TMA is avoided before reaching the main body 10, therefore a uniformity thickness of the aluminum oxide film is ensured.

The main body 10 with the aluminum oxide film is immersed into a deionized liquid with a temperature of 100° C. to increase a density of hydroxyls (—OH) on a surface of the aluminum oxide film. The solution is deionized water or alcohol. In this embodiment, the main body 10 is immersed into the deionized water for about 1-5 minutes.

A second chamber 70 is provided. The second chamber 70 contains a HDMS material 60 therein.

The main body 10 is positioned in the second chamber 70, the main body 10 and the HDMS material 60 are heated to about 100° C.-110° C., the temperature of the HDMS material 60 and the main body 10 is maintained for about five hours. A functional group of HDMS of a vapor of the HDMS material 60 is bonded to the hydroxyls on the aluminum oxide film, then a HDMS film is formed on the surface of the aluminum oxide film. Therefore, a film 12 compounded by aluminum oxide and HDMS is generated. In other words, the film 12 is the aluminum oxide film modified by the HDMS. The film 12 has both high hardness of aluminum oxide and hydrophobic property of silicane.

The functional group of the HDMS is bonded to the hydroxyls on the aluminum oxide film by self-forming molecules.

According to different requirements of the hydrophobic property, the above described steps can be repeated several times.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the disclosure.

What is claimed is:

1. A mold, comprising:
a main body, the main body defining a cavity therein; and
a film formed on a side surface of the cavity, the film being compounded with aluminum oxide and hexamethyldisilazane.

2. The mold of claim 1, wherein a thickness of the film is 100 nanometers.

3. A method for manufacturing a mold, comprising:
providing a main body of a mold, the main body defining a cavity therein;
positioning the main body in a first vacuum chamber;
heating the main body to a first predetermined temperature;
alternately injecting a material of trimethyl aluminum and a gas of oxygen into the first vacuum chamber to form an aluminum oxide film on a side surface of the cavity;
processing a surface of the aluminum oxide film to increase a density of hydroxyls on the surface of the aluminum oxide;
positioning the main body into a second vacuum chamber containing a material of hexamethyldisilazane therein; and
heating the main body and the hexamethyldisilazane to a second predetermined temperature to form a hexamethyldisilazane film on the aluminum oxide film.

4. The method of claim 3, wherein a pressure in the first vacuum chamber is kept at 10⁻³-10⁻⁵ torrs.

5. The method of claim 3, wherein the first predetermined temperature is 250° C.

6. The method of claim 3, wherein the main body is immerged into a deionized liquid to increase the density of hydroxyls.

7. The method of claim 6, wherein a temperature of the deionized liquid is kept at 100° C.

8. The method of claim 6, wherein the solution is selected from one of a group consisting of deionized water and alcohol.

9. The method of claim 6, wherein the main body is immerged into the solution for 1-5 minutes.

10. The method of claim 3, wherein the second predetermined temperature is in a range of 100° C.-110° C.

11. The method of claim 3, wherein a thickness of the aluminum oxide film is 100 nanometers.
